(19) United States
(12) Patent Application Publication
(10) Pub. No.: US 2015/0219996 A1
(43) Pub. Date: Aug. 6, 2015

(54) COMPOSITION FOR REMOVING SUBSTANCES FROM SUBSTRATES

(71) Applicant: Dynaloy, LLC, Kingsport, TN (US)

(72) Inventors: Richard Dalton Peters, Westfield, IN (US); Travis Acra, Ingalls, IN (US); Yuanmei Cao, Indianapolis, IN (US); Nichelle Maria Gilbert, Fishers, IN (US); Michael Tod Phenis, Markleville, IN (US); Kimberly Dona Pollard, Pendleton, IN (US); Joshua Cummins, Indianapolis, IN (US); Meng Guo, Indianapolis, IN (US); Donald James Pfettscher, Brownsburg, IN (US)

(73) Assignee: Dynaloy, LLC, Kingsport, TN (US)

(21) Appl. No.: 14/174,246

(22) Filed: Feb. 6, 2014

(51) Int. Cl. G03F 7/42; C11D 7/32; C11D 7/50; C11D 11/00

(52) U.S. Cl. CPC G03F 7/425; C11D 11/0047; C11D 7/3218; C11D 7/3209; C11D 7/5022

(57) ABSTRACT

Stripping compositions are described that are useful for removing organic substances from substrates, for example, electronic device substrates such as microelectronic wafers or flat panel displays. The stripping compositions may be suitable for removing photoresists, including acrylic-based negative dry film photoresist, from electronic devices. In one embodiment, the stripping compositions can include a polar protic solvent, an amine or alkanoamine, and a quaternary ammonium hydroxide. In one embodiment the stripping compositions can include a polar protic solvent and at least two alkanoamines. The stripping compositions may be free of polar aprotic solvents.

### BACKGROUND

Various substances, such as polymers, may be used in the manufacture of electronic devices, such as computer chips, memory devices, light emitting diodes (LEDs), and the like. In some cases, these substances may be used to form features on surfaces of substrates (e.g., semiconductor device substrates) included in electronic devices. In processing the substrates, these substances may be removed from the surfaces of the substrates. In one example, a layer of a substance may be disposed on at least a portion of the surface of a substrate and at least a portion of the layer may be removed during subsequent processing of the substrates. In another example, the substance may be a residue produced when a particular process is performed on the substrate. In any case, the effectiveness of the removal of the substances from the substrates can affect the quality of the operation of the semiconductor devices.

In an illustrative situation, photoresists and organic-based dielectrics may be used in the manufacture of semiconductor devices included in electronic devices. Photoresists, for example, may be used throughout semiconductor device fabrication in photolithographic operations. A photoresist may be exposed to actinic radiation through a photomask. For example, a polymeric photoresist can be applied to a substrate as a mask to define the placement of solder onto the substrate. After solder is deposited onto the substrate, the photoresist must be removed before the next step in the process can occur. In another example, a polymeric photoresist can be applied to a substrate as an etch mask used to define structures on the substrate that are created in an etch process. After the etch process, there is typically a polymeric residue remaining on the substrate that must be removed before the next step in the process can occur.

In some cases, a positive photoresist may be used. Exposure of the positive photoresist to actinic radiation may cause a chemical reaction resulting in a solubility increase in aqueous alkali that allows the exposed positive photoresist to be dissolved and rinsed away with developer. In other cases, a negative photoresist may be used. When the negative photoresist is exposed to actinic radiation, cross-linking of the polymer may occur in the exposed regions while leaving unexposed regions unchanged. The unexposed regions may be subject to dissolution and rinsing by a suitable developer chemistry. Following development, a resist mask may be left behind. The design and geometry of the resist mask may depend upon the positive or negative tone of the resist. Positive tone resist may match the design of the photomask, while a negative tone resist may provide a pattern that is opposite the photomask design.

Photoresists are used extensively in the packaging of microelectronic devices. In wafer level packaging, solder is applied directly to wafers that have completed the fabrication of the microelectronic devices but have not been diced into individual chips. A photoresist is used as the mask to define the placement of the solder on the wafers. After solder is deposited onto the wafer, the photoresist must be removed before the next step in the packaging process can occur. Typically in wafer level packaging, the photoresist can have a thickness greater than about 10 micrometers and sometimes as thick as about 120 micrometers. The photoresist can be positive or negative, and can be applied either as a liquid or a dry film. In wafer level packaging, the use of thick dry film negative photoresist is common.

Due to the thickness and cross-linked nature of thick dry film negative photoresist, the removal of this material after solder deposition can be difficult. In some cases, the photoresist can be deposited onto a dielectric material where the adhesion between the photoresist and the dielectric is strong enough to make removal of the photoresist difficult.

### SUMMARY

This summary is provided to introduce simplified concepts of compositions for removing substances from substrates such as, for example, photoresist from a semiconductor wafer. Additional details of example compositions are further described below in the Detailed Description. This summary is not intended to identify essential features of the claimed subject matter, nor is it intended for use in determining the scope of the claimed subject matter.

The disclosure is directed to compositions and processes to remove substances from substrates coated with dielectric films or metal layers. The substances can include photoresist and the substrates can include semiconductor wafers. The underlying dielectric and/or metal films may be patterned or continuous and may have features of other dissimilar materials patterned on the surface. The stripping compositions described in this disclosure effectively remove photoresists—including thick negative photoresists—without harming underlying substrates and without including chemicals that are restricted due to environmental health and safety rules and regulations.

According to an embodiment, a composition for removing substances from substrates may include about 1 wt. % to about 75 wt. % of a polar protic solvent, from about 1 wt. % to about 75 wt. % of an amine or alkanolamine, and from about 0.5 wt. % to about 10 wt. % of a quaternary ammonium hydroxide.

According to an embodiment, a composition for removing substances from substrates may include about 1 wt. % to about 75 wt. % of a polar protic solvent, from about 1 wt. % to about 75 wt. % of an amine or a first alkanolamine, and from about 1 wt. % to about 75 wt. % of a second alkanolamine.

The compositions may remove one or more substances from a substrate coated with a dielectric layer without harming the dielectric layer. The compositions may remove one or more substances from a substrate coated with a thin metal film, such as copper, without harming the thin metal film. The compositions may effectively remove one or more substances from a substrate without use of polar aprotic solvents (or with the use of minimal amounts of polar aprotic solvents) such as dimethylacetamide (DMAc), dimethylformamide (DMF), dimethylsulfoxide (DMSO), and/or N-methylpyrrolidone (NMP).

### DETAILED DESCRIPTION

The current invention describes compositions useful for removing organic substances, such as photoresists, from substrates coated with dielectric films or metal layers, such as for example, semiconductor wafers. The underlying dielectric and/or metal films may be patterned or continuous and may have features of other dissimilar materials patterned on the surface. The stripping compositions disclosed herein overcome health and environmental disadvantages of current cleaning technologies while still successfully removing thick negative photoresist from wafers.

The stripping compositions of the present disclosure may have application in the manufacture of a variety of devices including but not limited to semiconductor wafers, radio frequency (RF) devices, hard drives, memory devices, micro-electro-mechanical system (MEMS) devices, photovoltaics, displays, light-emitting diodes (LEDs), wafer level packaging and assembly processes, and solder bump fabrication. Other applications in which the stripping compositions that are disclosed may also be useful include, without limitation, removal of photoresists (back-end-of-line (BEOL), front-end-of-line (FEOL) processes), post-metallization lift off processes, post-etch residue removal, post implantation residues, lift-off, rework of passivation layers, and photoresist rework.

The words “stripping,” “removing,” and “cleaning” are used interchangeably throughout this specification. Likewise, the terms “stripping composition,” “stripping solution,” “cleaning composition,” and “cleaning solution” are used interchangeably. The acronym “PR” and “resist” are used interchangeably with the word “photoresist” from which they were derived. The terms “weight percent” or “wt. %” mean weight percent based on the total weight of the composition, unless otherwise indicated.

According to an embodiment, the present invention concerns removal of negative acrylic-based photoresist from a substrate using formulated cleaning solutions that do not contain any polar aprotic solvents. The stripping compositions overcome disadvantages with current cleaning technologies which may clean photoresist but do not conform to increasingly restrictive EHS policies and legislation.

In an embodiment of the current invention, the novel stripping compositions have been used to completely remove thick acrylic-based dry film negative photoresist from a tin-based lead-free solder bumped semiconductor wafer with exposed dielectric. In some applications, the photoresist may be very difficult to remove, such that current commercial formulated resist stripping compositions cannot remove the photoresist or can remove the photoresist but cause additional damage to permanent structures on the wafer surface. A need exists for new stripping compositions that are capable of removing these difficult-to-remove photoresists without harming the underlying substrate and that comply with new more restrictive HSE requirements.

Resist removal solutions that modify interfacial interactions, require contact with the interface between the resist and the underlying dielectric layer. Contact can be made at the wafer edge, however, in cases where the wafer is patterned, contact also can be made at the boundary between a feature and the photoresist. The effect is that the resist is removed faster from areas where there is a high density of features and more slowly from areas where there is a lower density of features.

In an embodiment of this invention, dielectric film(s) are comprised of any of (i) an organic polymeric film, (ii) an organic polymeric film impregnated with silicon or silica, or (iii) a silicon-containing inorganic film impregnated with organic, carbon-containing species. The dielectric film is the layer immediately under the photoresist and may be continuous but more commonly is discontinuous through the incorporation of features that have been patterned into the surface. A photoresist may adhere more strongly to a dielectric material than to a metal layer underneath the resist. Stronger adhesion increases the challenge of resist removal, especially when compatibility with the underlying dielectric is also required. Damage to dielectric films creates the potential for current leakage due to dielectric break down and shortens the lifetime of the devices into which they are put.

In some embodiments, the dielectric may be subjected to additional processing steps prior to coating with the photoresist. For example, the dielectric may be exposed to a dry chemical process, such as a plasma process to for example, change the surface roughness, and/or a high temperature process, such as a post deposition bake, and/or a wet chemical process such as a rinse to change the hydrophobicity or hydrophilicity of the dielectric before the photoresist is coated on the wafer.

In some embodiments, the patterned photoresist may be subjected to a high temperature step (annealing step) before resist removal, for example, a solder reflow process. The added thermal step may create additional cross-linking of the negative photoresist, making it even more difficult to remove. In some cases, the removal may become easier due to densification of the dielectric and changes at the interface during the high temperature process.

In another embodiment of the current invention, the inventive stripping compositions have been used to completely remove thick acrylic-based dry film negative photoresist from a tin-based lead-free solder bumped semiconductor wafer coated with a thin metal, metal alloy or metal amalgam film. Examples of metal films include, but are not limited to, Cu, Al, TiW, Ti, W, Sn, and SnAg. In cases where the polymer is removed from a metal surface, removal can occur using mechanisms that either undercut at the metal/PR film interface to begin lift-off of the PR film or that dissolve the PR film from the surface. Undercutting the PR film is less advantageous due to damage caused to the device. Formulations that swell-and-lift or dissolve the PR film may be preferable. Formulations that contain polar aprotic solvents, such as DMSO and NMP have been used extensively for the removal of negative tone photoresist in these applications due to the ease of solvent penetration into the acrylic-based polymers. However, changing environmental health and safety (EHS) requirements limit the use of DMSO and NMP.

Novel stripping compositions disclosed herein provide formulations with a cleaning performance that is similar or better than formulations using NMP and DMSO while including minimal amounts of polar aprotic solvent or without using any polar aprotic solvents. Thus, the stripping compositions described herein are unique in their combination of ability to remove difficult-to-strip photoresists and compliance with restrictive EHS regulations.

According to an embodiment, the stripping compositions can include a polar protic solvent, an amine or alkanolamine, and a quaternary ammonium hydroxide. The stripping compositions may be free from any polar aprotic solvents.

The polar protic solvent is a hydrocarbon-containing solvent with at least one primary hydroxyl group. It may include, but is not limited to, furfuryl alcohol (FFA), tetrahydrofurfuryl alcohol (THFA), benzyl alcohol, cyclohexanol, (4-methylcyclohexyl)methanol, hydroxymethylcyclohexane, m-cresol, or a mixture thereof. In some embodiments, the polar protic solvent may be a cyclic hydrocarbon solvent with at least one primary hydroxyl group. The polar protic solvent may be present in the stripping composition from about 1 wt. % to about 90 wt. %, from about 10 wt. % to about 75 wt. %, or from about 25 wt. % to about 60 wt. %. In an embodiment the polar protic solvent may be present in an amount that is at least 1 wt. %, at least 10 wt. %, or at least 25 wt. %. In an embodiment, the polar protic solvent may be present at an amount no greater than 90 wt. %, no greater than 75 wt. %, no greater than 60 wt. %. Alternatively, the polar protic solvent may be present in an amount of less than 40 wt %, less than 30 wt %, or less than 25 wt. % or the polar protic solvent may be present in an amount of greater than 60 wt. %, 70 wt. %, or 80 wt. %.

Table 1 indicates the flash points and boiling points of some illustrative solvents.

TABLE 1

| Solvent | Boiling point (° C.) | Flash point (° C.) |
|---|---|---|
| THFA | 178 | 75 |
| FFA | 170 | 65 |
| Benzyl alcohol | 205 | 96 |
| cyclohexanol | 161 | 67 |
| (4-methylcyclohexyl)methanol | 202 | 80 |
| hydroxymethylcyclohexane | 181 | 71 |
| m-cresol | 203 | 86 |

According to an embodiment, the stripping composition may include an amine. The amine may include, but is not limited to, diethylenetriamine (DETA), triethylenetetramine (TETA), tetraethylenepentamine, benzylamine, dimethylbenzylamine, malonamide, tetrandydrofurfurylamine, furfuyl amine, 2-pyrrolidinone or a mixture thereof. The amine may be present in the stripping composition from about 1 wt. % to about 75 wt. %, from about 4 wt. % to about 60 wt. %, or from about 7 wt. % to about 50 wt. %. In an embodiment the amine may be present in an amount that is at least 1 wt. %, at least 4 wt. %, or at least 7 wt. %. In an embodiment the amine may be present in an amount that no greater than 75 wt. %, no greater than 60 wt. %, or no greater than 50 wt. %.

According to one embodiment, the stripping compositions may include an alkanolamine. The alkanolamine can have at least two carbon atoms, at least one amino substituent and at least one hydroxyl substituent, wherein the amino and hydroxyl substituents are attached to two different carbon atoms. The amino substituent may be a primary, secondary or tertiary amine. The alkanolamine may include, but is not limited to, aminoethylethanolamine (AEEA), dimethylaminoethanol (DMAE), monoethanolamine (MEA), N-methylethanolamine, N-ethylethanolamine, N-propylethanolamine, N-butylethanolamine, diethanolamine, triethanolamine, N-methyldiethanolamine, N-ethyldiethanolamine, monoisopropanolamine (MIPA), diisopropanolamine, triisopropanolamine, N-methylisopropanolamine, N-ethylisopropanolamine, N-propylisopropanolamine, 2-aminopropane-1-ol, N-methyl-2-aminopropane-1-ol, N-ethyl-2-aminopropane-1-ol, 1-aminopropane-3-ol, N-methyl--1-aminopropane-3-ol, N-ethyl-1-aminopropane-3-ol, 1-aminobutane-2-ol, N-methyl-1-aminobutane-2-ol, N-ethyl-1-aminobutane-2-ol, 2-aminobutane-1-ol, N-methyl-2-aminobutane-1-ol, N-ethyl-2-aminobutane-1-ol, 3-aminobutane-1-ol, N-methyl-3-aminobutane-1-ol, N-ethyl-3-aminobutane-1-ol, 1-aminobutane-4-ol, N-methyl-1-aminobutane-4-ol, N-ethyl-1-aminobutane-4-ol, 1-amino-2-methylpropane-2-ol, 2-amino-2-methylpropane-1-ol, 1-aminopentane-4-ol, 2-amino-4-methylpentane-1-ol, 2-aminohexane-1-ol, 3-aminoheptane-4-ol, 1-aminooctane-2-ol, 5-aminooctane-4-ol, 1-aminopropane-2,3-diol, 2-aminopropane-1,3-diol, tris(oxymethyl)aminomethane, 1,2-diaminopropane-3-ol, 1,3-diaminopropane-2-ol, 2-(2-aminoethoxy)ethanol, (DGA), hydroxyethylmorpholine, 1-(2-hydroxyethyl)piperdine, N-(2-hydroxyethyl)-2-pyrrolidone, or a mixture thereof. The alkanolamine may be present in the stripping composition from about 1 wt. % to about 75 wt. %, from about 4 wt. % to about 60 wt. %, or from about 7 wt. % to about 50 wt. %. In an embodiment, the alkanolamine may be present in an amount that is at least 1 wt. %, at least 4 wt. %, or at least 7 wt. %. In an embodiment the alkanolamine may be present in an amount that is no greater than 75 wt. %, no greater than 60 wt. %, or no greater than 50 wt. %.

According to an embodiment, the stripping compositions can include a quaternary ammonium hydroxide. For example, the quaternary ammonium hydroxide may include, but is not limited to, tetramethylammonium hydroxide (TMAH), tetraethylammonium hydroxide (TEAH), dimethyldipropyl ammonium hydroxide (DMDPAH), benzyltrimethylammonium hydroxide (BTMAH), tetrapropylammonium hydroxide (TPAH), tetrabutylammonium hydroxide (TBAH), or a mixture thereof. The quaternary ammonium hydroxide may be present in the stripping compositions from about 0.5 wt. % to about 10 wt. %, from about 1 wt. % to about 8 wt. %, or from about 2 wt. % to about 6 wt. %. In an embodiment, the quaternary ammonium hydroxide may be present in an amount that is at least 0.5 wt. %, at least 1 wt. %, or at least 2 wt. %. In an embodiment, the quaternary ammonium hydroxide may be present in an amount that is no greater than 10 wt. %, no greater than 8 wt. %, or no greater than 6 wt. %.

According to some embodiments, the stripping compositions may further include a polar aprotic solvent in an amount of no greater than 20 wt %, no greater than 10 wt. %, no greater than 5 wt. %, no greater than 2 wt. % or not greater than 1 wt. %. Exemplary polar aprotic solvents include, but are not limited to, dimethylacetamide (DMAc), dimethylformamide (DMF), dimethylsulfoxide (DMSO), 1-formylpiperidine, and/or N-methylpyrrolidone (NMP).

According to one embodiment, the stripping compositions may include a polar protic solvent, an amine or a first alkanolamine, and a second alkanolamine. The striping compositions may also include a third alkanolamine. The stripping compositions may be free from any polar aprotic solvents.

The polar protic solvent is a hydrocarbon-containing solvent with at least one primary hydroxyl group. It may include, but is not limited to, furfuryl alcohol (FFA), tetrahydrofurfuryl alcohol (THFA), benzyl alcohol, cyclohexanol, (4-methylcyclohexyl)methanol, hydroxymethylcyclohexane, m-cresol, or a mixture thereof. In some embodiments, the polar protic solvent may be a cyclic hydrocarbon solvent with at least one primary hydroxyl group. The polar protic solvent may be present in the stripping composition from about 1 wt. % to about 90 wt. %, from about 10 wt. % to about 75 wt. %, or from about 20 wt. % to about 60 wt. %. In an embodiment the polar protic solvent may be present in an amount that is at least 1 wt. %, at least 10 wt. %, or at least 20 wt. %. In an embodiment, the polar protic solvent may be present at an amount no greater than 90 wt. %, no greater than 75 wt. %, or no greater than 60 wt. %.

According to one embodiment, the stripping compositions may include two or more alkanolamines. The alkanolamines can have at least two carbon atoms, at least one amino substituent and at least one hydroxyl substituent, wherein the amino and hydroxyl substituents are attached to two different carbon atoms. The amino substituent may be a primary, secondary, or tertiary amine. The alkanolamine may include, but is not limited to, aminoethylethanolamine (AEEA), dimethylaminoethanol (DMAE), monoethanolamine (MEA), N-methylethanolamine, N-ethylethanolamine, N-propylethanolamine, N-butylethanolamine, diethanolamine, triethanolamine, N-methyldiethanolamine, N-ethyldiethanolamine, monoisopropanolamine (MIPA), diisopropanolamine, triisopropanolamine, N-methylisopropanolamine, N-ethylisopropanolamine, N-propylisopropanolamine, 2-aminopropane-1-ol, N-methyl-2-aminopropane-1-ol, N-ethyl-2-aminopropane-1-ol, 1-aminopropane-3-ol, N-methyl--1-aminopropane-3-ol, N-ethyl-1-aminopropane-3-ol, 1-aminobutane-2-ol, N-methyl-1-aminobutane-2-ol, N-ethyl-1-aminobutane-2-ol, 2-aminobutane-1-ol, N-methyl-2-aminobutane-1-ol, N-ethyl-2-aminobutane-1-ol, 3-aminobutane-1-ol, N-methyl-3-aminobutane-1-ol, N-ethyl-3-aminobutane-1-ol, 1-aminobutane-4-ol, N-methyl-1-aminobutane-4-ol, N-ethyl-1-aminobutane-4-ol, 1-amino-2-methylpropane-2-ol, 2-amino-2-methylpropane-1-ol, 1-aminopentane-4-ol, 2-amino-4-methylpentane-1-ol, 2-aminohexane-1-ol, 3-aminoheptane-4-ol, 1-aminooctane-2-ol, 5-aminooctane-4-ol, 1-aminopropane-2,3-diol, 2-aminopropane-1,3-diol, tris(oxymethyl)aminomethane, 1,2-diaminopropane-3-ol, 1,3-diaminopropane-2-ol, 2-(2-aminoethoxy)ethanol, (DGA), hydroxyethylmorpholine, 1-(2-hydroxyethyl)piperdine, N-(2-hydroxyethyl)-2-pyrrolidone, or a mixture thereof.

The first alkanolamine may be present in the composition from about 1 wt. % to about 75 wt. %, from about 4 wt. % to about 60 wt. % or from about 7 wt. % to about 50 wt. %. In an embodiment the first alkanolamine may be present in an amount that is at least 1 wt. %, at least 4 wt. %, or at least 7 wt. %. In an embodiment the first alkanolamine may be present in an amount that is no greater than 75 wt. %, no greater than 60 wt. % or no greater than 50 wt. %. The second alkanolamine may be present in the composition from about 0.5 wt. % to about 50 wt. %., from about 1 wt. % to about 25 wt. %, or from about 2 wt. % to about 20 wt %. In an embodiment, the second alkanolamine may be present in an amount that is at least 0.5 wt. %, at least 1 wt. %, or at least 2 wt. %. In an embodiment the second alkanolamine may be present in an amount that is no greater than 50 wt. %, no greater than 25 wt. % or no greater than 20 wt. %. The third alkanolamine may be present in the composition from about 0.5 wt. % to about 30 wt. %, from about 1 wt. % to about 25 wt. %, or from about 2 wt. % to about 20 wt. %. In an embodiment the third alkanolamine may be present in an amount that is at least 0.5 wt. %, at least 1 wt. %, or at least 2 wt. %. In an embodiment the third alkanolamine may be present in an amount that is no greater than 30 wt. %, no greater than 25 wt. %, or no greater than 20 wt. %.

In an embodiment stripping compositions may include an amine in place of the first alkanolamine. The amine may include, but is not limited to, diethylenetriamine (DETA), triethylenetetramine (TETA), tetraethylenepentamine, dimethylbenzylamine, malonamide, tetrandydrofurfurylamine, furfuyl amine, 2-pyrrolidinone, or a mixture thereof. The amine may be present in the stripping composition from about 1 wt. % to about 75 wt. %, from about 4 wt. % to about 60 wt. %, or from about 7 wt. % to about 50 wt. %. In an embodiment the amine may be present in an amount that is at least 1 wt. %, at least 4 wt. %, or at least 7 wt. %. In an embodiment the amine may be present in an amount that no greater than 75 wt. %, no greater than 60 wt. %, or no greater than 50 wt. %.

The stripping compositions according to the present invention can be used to remove photoresist from a number of different substrates and via a number of different methods including methods that involve immersing the substrate. The substrate can be contacted with the stripping composition to remove at least a portion of one or more substances from the substrate. The stripping composition can dissolve a targeted substance (e.g., photoresist) that is disposed on the substrate and/or cause the targeted substance to be released from the substrate. In particular, the stripping composition can remove at least about 75% of the targeted substance from the substrate, at least about 85% of the targeted substance from the substrate, at least about 95% of the targeted substance from the substrate, or at least about 99% of the targeted substance from the substrate. Additionally, the stripping composition can remove substantially all of the substance from the substrate. The stripping composition can include any formulation described herein.

The stripping compositions provided in this disclosure can be used to remove polymeric resist materials present in a single layer or certain types of bilayer resists. For example, bilayer resists typically have either a first inorganic layer covered by a second polymeric layer or can have two polymeric layers. Utilizing the methods taught below, a single layer of polymeric resist can be effectively removed from a standard wafer having a single polymer layer. The same methods can also be used to remove a single polymer layer from a wafer having a bilayer composed of a first inorganic layer and a second or outer polymer layer. Finally, two polymer layers can be effectively removed from a wafer having a bilayer composed of two polymeric layers. The new stripping compositions can be used to remove one, two or more resist layers.

In an embodiment, the substrate can be immersed in the stripping composition. For example, the substrate can be immersed in a bath of the stripping composition. In an embodiment, the bath may hold about 100 mL of stripping composition. Alternatively, the stripping composition can be applied to one or more sides of the substrate. To illustrate, the stripping composition can be dispensed onto one or more sides of the substrate. The stripping composition can also be coated onto one or more sides of the substrate. When immersing a substrate, agitation of the stripping composition may facilitate photoresist removal. Agitation can be effected by mechanical stirring, circulating, or by bubbling an inert gas through the stripping composition.

Contacting the substance on the substrate with the stripping composition can also include heating the stripping composition, the substrate, or both to a temperature that provides for the removal of the substance within a specified period of time. The stripping composition, the substrate, or both can be heated to a temperature no greater than about 130° C., no greater than about 99° C., or no greater than about 80° C. Additionally, the stripping composition, the substrate, or both can be heated to a temperature of at least about 30° C., at least about 45° C., or at least about 60° C. Furthermore, the stripping composition, the substrate, or both can be heated to a temperature included in a range of from about 40° C. to about 130° C., from about 50° C. to about 105° C., or from about 60° C. to about 90° C. An amount of heat to increase a temperature of the stripping composition and/or substrate can be provided by a heat source, such as a conductive heat source, radiative heat source, or a convective heat source.

The substrate can be contacted with the stripping composition for a specified duration that is no greater than about 120 minutes, no greater than about 60 minutes, no greater than about 30 minutes, or no greater than about 10 minutes. Additionally, the substrate can be contacted with the stripping composition for a specified duration that is at least about 5 minutes, at least about 20 minutes, or at least about 30 minutes. The stripping composition, the substrate, or both can also be heated for a time range of about 5 minutes to about 90 minutes.

After being contacted with the stripping composition for a period of time, the substrate can then be rinsed and dried. For example, the substrate can be subjected to one or more rinse operations using deionized water (DI) and/or low boiling point solvents such as acetone and isopropyl alcohol (IPA). The substrate can be rinsed using multiple operations, such as a DI rinse followed by an IPA rinse. Alternatively, the substrate can be rinsed in IPA followed by a DI rinse. The order in which these rinsing steps is applied may vary, and rinsing steps may be repeated multiple times. Lastly, the substrate can be subjected to one or more drying operations, such as drying using a stream of one or more of air, nitrogen, or argon, or surface tension gradient drying (Marangoni effect).

In an embodiment, the substrate or “wafer” can be placed inside a holder with a well that holds a volume of the stripping composition. A volume of stripping composition may be added to the well such that the thickness of the liquid coating on top of the wafer is less than about 4 mm thick, or may be less than about 3.5 mm thick, or less than about 3 mm thick, or less than about 2.5 mm thick, or less than about 2 mm thick. Alternatively, the thickness of the formulation may be greater than about 0.5 mm thick, greater than about 1 mm thick, or greater than about 1.5 mm thick. The thickness of the liquid coating above the wafer may be thinner or thicker depending on the application and the substance (e.g., resist) to be removed.

Contacting the substance on the substrate in the holder with the stripping composition can also include heating the stripping composition, the substrate, or both to a temperature that provides for the removal of the substance within a specified period of time. The stripping composition, the substrate, or both can be heated to a temperature no greater than about 130° C., no greater than about 120° C., or no greater than about 110° C. Alternatively, the stripping composition, the substrate, or both can be heated to a temperature of at least about 90° C., at least about 100° C., or at least about 105° C. Furthermore, the stripping composition, the substrate, or both can be heated to a temperature included in a range of about 95° C. to about 110° C. An amount of heat to increase a temperature of the stripping composition and/or substrate can be provided by a heat source, such as a conductive heat source, a radiative heat source, or a convective heat source.

The substrate can be contacted with the stripping composition for a specified duration that is no greater than about 20 minutes, no greater than about 12 minutes, or no greater than about 8 minutes. Additionally, the substrate can be contacted with the stripping composition for a specified duration that is at least about 1 minute, at least about 3 minutes, or at least about 10 minutes. The stripping composition, the substrate, or both can also be heated for a time range of from 1 minute to about 12 minutes, from about 3 minutes to about 10 minutes, or from about 4 minutes to about 8 minutes.

Following heating, the substrate or wafer may be removed from the well, rinsed, and dried. For example, the substrate or wafer can be rinsed with pressurized water. In an embodiment, the pressurized water may be provided from a fan spray nozzle. The pressurized water may be provided at about 20 pounds square inch (psi) to about 70 psi or from about 30 psi to about 60 psi. The pressurized water may also be provided at about 45 psi. The sample may be rinsed with pressurized water for about 10 seconds to about 40 seconds. The sample may then be rinsed with a low boiling point solvent such as acetone or IPA. The order in which these rinsing steps is applied may vary, and rinsing steps may be repeated multiple times. Finally, the sample can be subjected to one or more drying operations, such as drying using a stream of one or more of air, nitrogen, or argon, drying by spin drying, and surface tension gradient drying (Marangoni effect).

Although the subject matter has been described in language specific to structural features and/or methodological acts, it is to be understood that the subject matter defined in the appended claims is not necessarily limited to the specific features or acts described. Rather, the specific features and acts are disclosed as exemplary forms of implementing the claims.

### EXAMPLES

In the examples below, various stripping compositions were used to remove thick-acrylic-based dry film, filled with a tin-based lead-free solder, and patterned on a dielectric material (Examples 1-4) or to remove negative spin-on film resist, filled with a tin-based lead-free solder, and patterned on a film of physical vapor deposited (PVD) copper metal from semiconductor wafers (Examples 5 and 6). Resist removal was performed using one of two techniques: an immersion process or a higher temperature, short process time cleaning process. Both removal techniques were performed after a reflow process.

For the immersion process, coupon-sized samples of semiconductor wafers were processed in beakers. Beakers were filled with 100 mL of a stripping composition and heated to the target temperature of 70° C. When the stripping composition was at the target temperature, a coupon was placed in a holder in the beaker, and slight agitation was provided by a stir bar. Temperature was maintained at the target temperature of 70° C. throughout the process. After a total processing time of 30 minutes, the coupons were removed from the beaker, rinsed with DI water and IPA, and dried with a stream of air.

In the higher temperature, short process time process coupon-sized samples of a semiconductor wafer were processed on a hot plate. Coupons were placed inside a holder with a well with a volume of 2.7 mL. The well was partially filled with 1.8 mL of a stripping composition to cover the coupon, resulting in a thickness of stripping composition of about 2 mm on top of the coupon. The holder was placed on the hot plate such that the liquid temperature reached about 100-105° C. The samples were heated for different times depending on the particular stripping composition being tested. Heating times are shown for the specific examples below. After heating, the coupon was then removed from the well using tweezers and rinsed with pressurized water at 45 psi via a fan spray nozzle for 10 seconds. Finally, the coupon was rinsed with IPA and blown dry with a stream of air.

For the experiments described below, solution homogeneity of the stripping composition, resist removal of the thick-acrylic-based dry film resist, and dielectric compatibly or copper compatibility (depending on the substrate underlying the resist in a particular sample) were observed. “Good” solution homogeneity was recorded if a sample of the stripping composition was left undisturbed at about 23° C. for 48 hrs and remained homogeneous. “Poor” homogeneity was defined as a stripping composition that precipitated solids when left undisturbed at room temperature for 48 hrs. Resist removal is defined as “clean” if all resist was removed from the wafer coupon surface; as “mostly clean” if at least 80% of the resist was removed from the surface; “partly clean” if about 50% of the resist was removed from the surface; and “not clean” if <50% of the resist was removed from the surface. Dielectric compatibility was recorded as “unacceptable” if significant damage, cracking, swelling or increased roughness were found; “acceptable,” if only a small amount of dielectric roughening with no cracking or swelling was found; and “good” if no dielectric roughening, cracking or swelling was found. If resist removal was not effective enough to expose the dielectric surface, the dielectric compatibility was recorded as not applicable (NA). Copper compatibility was recorded as “unacceptable” if the copper film was completely removed or changed color significantly; “acceptable,” if only small amounts of oxidation were found on the copper film; and “good” if the surface of the copper metal appeared pristine and no oxidation was found.

The follow abbreviations are used in the various compositions listed below: AEEA=aminoethylethanolamine; DETA=diethylenetriamine; DMAE=2-dimethylaminoethanol; DMDPAH=dimethyldipropyl ammonium hydroxide; DMSO =Dimethylsulfoxide; FFA=furfuryl alcohol; MEA=monoethanolamine MIPA=monoisopropanolamine; MMB=3-methoxy 3-methylbutanol; PG=propylene glycol; TEAH=tetraethylammonium hydroxide; THFA=tetrahydrofurfuryl alcohol; and TMAH=tetramethylammonium hydroxide.

### Example 1

Table 2 lists 6 stripping compositions that were tested for Example 1 using the immersion process and semiconductor wafers with dielectric substrates. All the stripping compositions in Table 2 include a quaternary ammonium hydroxide (e.g., TMAH or DMDPAH). The results shown in Table 2 illustrate that novel stripping compositions 1-2 have performance advantages over commercially available compositions 3-5 that use DMSO. The heating time for all compositions in Table 2 was 30 minutes.

TABLE 2

| Com- | | Homogeneous | Resist | Dielectric |
|---|---|---|---|---|
| posi- | Formulation | Solution | Removal | Com- |
| tion | Composition | Stability | Results | patibility |
| 1 | 65 wt. % benzyl | Poor | Clean | Good |
| | amine, | | | |
| | 30.4 wt. % benzyl | | | |
| | alcohol, | | | |
| | 2.3 wt. % TMAH, | | | |
| | 2.3 wt. % H₂O | | | |
| 2 | 25 wt % THFA, | Good | Mostly clean | Good |
| | 55 wt. % MEA, | | | |
| | 4 wt. % DMDPAH, | | | |
| | 16 wt. % PG | | | |
| 3 | 71 wt % DMSO, | Good | Not clean | NA |
| | 24 wt % DMAE, | | | |
| | 2.5 wt % TMAH, | | | |
| | 2.5 wt % H₂O | | | |
| 4 | 84 wt % DMSO, | Good | Not clean | NA |
| | 3 wt % MEA, | | | |
| | 2.5 wt % TMAH, | | | |
| | 10 wt % MMB, | | | |
| | 0.5 wt % H₂O | | | |
| 5 | 82 wt % DMSO, | Good | Not clean | NA |
| | 3 wt % MEA, | | | |
| | 10 wt % MMB, | | | |
| | 2.5 wt % TMAH, | | | |
| | 2.5 wt % H₂O | | | |

### Example 2

Table 3 shows test results for 3 stripping compositions that did not contain a quaternary ammonium hydroxide but contained multiple alkanolamines (e.g., MEA, DMAE, and MIPA). Example 2 used the immersion process and semiconductor wafers with dielectric substrates. The heating time for all compositions in Example 2 was 30 minutes. Homogeneous stripping composition stability was good for all compositions in Example 2. The results shown in Table 3 illustrate that novel stripping compositions 7-8 have better dielectric compatibility than stripping composition 7 made using a polar aprotic solvent (i.e., DMSO).

TABLE 3

| | Formulation | Resist Removal | Dielectric |
|---|---|---|---|
| Composition | Composition | Results | Compatibility |
| 6 | 55 wt. % MEA, | Clean | Unacceptable |
| | 25 wt. % DMSO, | | |
| | 10 wt. % DMAE, | | |
| | 10 wt. % MIPA | | |
| 7 | 55 wt. % MEA, | Clean | Good |
| | 25 wt. % THFA, | | |
| | 10 wt. % DMAE, | | |
| | 10 wt. % MIPA | | |
| 8 | 55 wt. % MEA, | Mostly clean | Good |
| | 25 wt. % FFA, | | |
| | 10 wt. % DMAE, | | |
| | 10 wt. % MIPA | | |

### Example 3

Table 4 shows test results for 9 stripping compositions without ammonium hydroxides to evaluate the effect of amines and polar protic solvents on efficacy for resist removal. Example 3 used the immersion process and semiconductor wafers with dielectric substrates. The heating time for all compositions in Example 3 was 30 minutes. Homogeneous stripping composition stability was good for all compositions in Example 3. The results shown in Table 3 illustrate effectiveness of stripping compositions 10-18 for removal of photoresists. Selection of a particular polar protic solvent (e.g., THFA, FFA, or benzyl alcohol) and amines (e.g, MEA, DMAE, MIPA, DETA, or AEEA) can optimize the system for a specific photoresist removal application.

TABLE 4

| | | Resist Removal | Dielectric |
|---|---|---|---|
| Composition | Formulation Composition | Results | Compatibility |
| 9 | 55 wt. % MEA, | Clean | Good |
| | 25 wt. % THFA, | | |
| | 10 wt. % DMAE, | | |
| | 10 wt. % MIPA | | |
| 10 | 55 wt. % MEA, | Mostly clean | Good |
| | 25 wt. % FFA, | | |
| | 10 wt. % DMAE, | | |
| | 10 wt. % MIPA | | |
| 11 | 55 wt. % MEA, | Mostly clean | Acceptable |
| | 25 wt. % benzyl alcohol, | | |
| | 10 wt. % DMAE, | | |
| | 10 wt. % MIPA | | |
| 12 | 55 wt. % MEA, | Mostly clean | Acceptable |
| | 25 wt. % THFA, | | |
| | 10 wt. % DMAE, | | |
| | 10 wt. % DETA | | |
| 13 | 55 wt. % MEA, | Mostly clean | Acceptable |
| | 25 wt. % THFA, | | |
| | 10 wt. % DMAE, | | |
| | 10 wt. % AEEA | | |
| 14 | 35 wt. % MEA, | Partially clean | Acceptable |
| | 25 wt. % THFA, | | |
| | 20 wt. % DMAE, | | |
| | 20 wt. % MIPA | | |
| 15 | 15 wt. % MEA, | Partially clean | Acceptable |
| | 75 wt. % THFA, | | |
| | 5 wt. % DMAE, | | |
| | 5 wt. % MIPA | | |
| 16 | 15 wt. % MEA, | Partially clean | Acceptable |
| | 65 wt. % THFA, | | |
| | 5 wt. % DMAE, | | |
| | 5 wt. % MIPA, | | |
| | 10 wt. % H₂O | | |
| 17 | 15 wt. % MEA, | Partially clean | Acceptable |
| | 72 wt. % THFA, | | |
| | 5 wt. % DMAE, | | |
| | 5 wt. % MIPA, | | |
| | 3 wt. % glycerine | | |

### Example 4

Table 5 shows test results for 3 stripping compositions used in the higher temperature, short process time process applied to semiconductor wafers with dielectric substrates. Table 4 includes stripping compositions 18-20 that include quaternary ammonium hydroxides (e.g., TMAH and TEAH) as well as a composition 18 that does not include quaternary ammonium hydroxides but does include multiple alkanolamines (e.g., MEA, DMAE, and MIPA). The results shown in Table 5 illustrate that the stripping compositions are not process dependent but may be used in a variety of different cleaning processes.

TABLE 5

| | | Homogeneous | Heating | Resist | |
|---|---|---|---|---|---|
| | Formulation | Solution | Time | Removal | Dielectric |
| Composition | Composition | Stability | (min) | Results | compatibility |
| 18 | 55 wt. % MEA, | Good | 10 | Clean | Good |
| | 25 wt. % THFA, | | | | |
| | 10 wt. % DMAE, | | | | |
| | 10 wt. % MIPA | | | | |
| 19 | 65 wt. % benzyl | Poor | 6 | Clean | Acceptable |
| | amine, | | | | |
| | 30.4 wt. % benzyl | | | | |
| | alcohol, | | | | |
| | 2.3 wt. % TMAH, | | | | |
| | 2.3 wt. % H₂O | | | | |
| 20 | 49.8 wt. % furfuryl | Good | 6 | Clean | Good |
| | alcohol, | | | | |
| | 31 wt. % H₂O, | | | | |
| | 15 wt. % MEA, | | | | |
| | 4 wt. % TEAH, | | | | |
| | 0.2 wt. % surfactant | | | | |

The stripping compositions can also contain an optional surfactant, typically at levels in the range of about 0.01% to about 3%. One example of a fluorosurfactant is DuPont FSO (fluorinated telomere B monoether with polyethylene glycol (50%), ethylene glycol (25%), 1,4-dioxane (<0.1%), water 25%). Other useful surfactants include but are not limited to, Glycol Palmitate, Polysorbate 80, Polysorbate 60, Polysorbate 20, Sodium Lauryl Sulfate, Coco Glucoside, Lauryl-7 Sulfate, Sodium Lauryl Glucose Carboxylate, Lauryl Glucoside, Disodium Cocoyl Glutamate, Laureth-7 Citrate, Disodium Cocoamphodiacetate, nonionic Gemini surfactants including, for example, those sold under the tradename ENVIROGEM 360, nonionic fluorosurfactants including, for example, those sold under the tradename Zonyl FSO, ionic fluorinated surfactants including, for example, those sold under the tradename Capstone FS-10, Oxirane polymer surfactants including, for example, those sold under the tradename SURFYNOL 2502, and poloxamine surfactants, including, for example, those sold under the tradename TETRONIC 701 and mixtures thereof.

### Example 5

Table 6 shows test results for a stripping composition with a quaternary ammonium hydroxide using the immersion process to remove 50 μm-thick acrylic-based negative spin-on resist JSR THB-S375N from a semiconductor wafer with a copper metal substrate. The heating time was 60 minutes. Homogeneous stripping composition stability was good for stripping composition in example 5. The results shown in Table 6 illustrate favorable results similar to stripping compositions 1-2 but used with a copper metal substrate.

TABLE 6

| | Formulation | Resist Removal | Copper |
|---|---|---|---|
| Composition | Composition | Results | Compatibility |
| 21 | 72.5 wt. % THFA, | Clean | Good |
| | 10 wt. % DETA, | | |
| | 7.5 wt. % MIPA, | | |
| | 8 wt. % PG, | | |
| | 2 wt. % DMDPAH | | |

### Example 6

Table 7 shows test results for a stripping composition used with the higher temperature, short process time process. Stripping composition 22 included three alkanolamines, but did not include a quaternary ammonium hydroxide and was used to remove 15 μm-thick negative spin-on resist AZ 15nXT from a semiconductor wafer with a copper metal substrate. The heating time was 1 minute and homogeneous stripping composition stability was good. The results shown in Table 7 illustrate removal of the photoresist from a metallic surface showing cleaning capability in multiple device manufacturing integration processes.

TABLE 7

| | | Heating | Resist | |
|---|---|---|---|---|
| | Formulation | Time | Removal | Copper |
| Composition | Composition | (min) | Results | Compatibility |
| 22 | 55 wt. % MEA, | 1 | Clean | Good |
| | 25 wt. % THFA, | | | |
| | 10 wt. % DMAE, | | | |
| | 10 wt. % MIPA | | | |

### Illustrative Embodiments

While Applicant's disclosure includes reference to specific embodiments above, it will be understood that modifications and alterations in the embodiments disclosed may be made by those practiced in the art without departing from the spirit and scope of the invention. All such modifications and alterations are intended to be covered. As such the embodiments listed below are merely illustrative and not limiting.

Embodiment 1: A composition comprising from about 1 wt. % to about 90 wt. %. of a polar protic solvent; from about 1 wt. % to about 75 wt. % of an amine or alkanolamine; and from about 0.5 wt. % to about 10 wt. % of quaternary ammonium hydroxide.

Embodiment 2: The composition of embodiment 1, wherein the polar protic solvent is present from about 25 wt. % to about 75 wt. %.

Embodiment 3: The composition of embodiment 1, wherein the polar protic solvent is present in an amount of less than 40 wt %.

Embodiment 4: The composition of embodiment 1, wherein the polar protic solvent is present in an amount of greater than 60 wt %.

Embodiment 5: The composition of embodiments 1-4, further comprising a polar aprotic solvent in an amount no greater than about 20 wt. %.

Embodiment 6: The composition of embodiments 1-5, wherein the amine or alkanolamine is present in an amount from about 20 wt. % to about 50 wt. %.

Embodiment 7: The composition of embodiments 1-6, wherein the polar protic solvent is furfuryl alcohol (FFA), tetrahydrofurfuryl alcohol (THFA), benzyl alcohol, cyclohexanol, (4-methylcyclohexyl)methanol, hydroxymethylcyclohexane, m-cresol, or a mixture thereof.

Embodiment 8: The composition of embodiments 1-7, wherein the polar protic solvent comprises a cyclic molecule.

Embodiment 9: The composition of embodiments 1-8, wherein the amine is diethylenetriamine (DETA), triethylenetetramine (TETA), tetraethylenepentamine, dimethylbenzylamine, malonamide, tetrahydrofurfurylamine, furfuyl amine, or a mixture thereof.

Embodiment 10: The composition of embodiments 1-9, wherein the alkanolamine is aminoethylethanolamine (AEEA), dimethylaminoethanol (DMAE), monoethanolamine (MEA), N-methylethanolamine, N-ethylethanolamine, N-propylethanolamine, N-butylethanolamine, diethanolamine, triethanolamine, N-methyldiethanolamine, N-ethyldiethanolamine, monoisopropanolamine (MIPA), diisopropanolamine, triisopropanolamine, N-methylisopropanolamine, N-ethylisopropanolamine, N-propylisopropanolamine, 2-aminopropane-1-ol, N-methyl-2-aminopropane-1-ol, N-ethyl-2-aminopropane-1-ol, 1-aminopropane-3-ol, N-methyl-1-aminopropane-3-ol, N-ethyl-1-aminopropane-3-ol, 1-aminobutane-2-ol, N-methyl-1-aminobutane-2-ol, N-ethyl-1-aminobutane-2-ol, 2-aminobutane-1-ol, N-methyl-2-aminobutane-1-ol, N-ethyl-2-aminobutane-1-ol, 3-aminobutane-1-ol, N-methyl-3-aminobutane-1-ol, N-ethyl-3-aminobutane-1-ol, 1-aminobutane-4-ol, N-methyl-1-aminobutane-4-ol, N-ethyl-1-aminobutane-4-ol, 1-amino-2-methylpropane-2-ol, 2-amino-2-methylpropane-1-ol, 1-aminopentane-4-ol, 2-amino-4-methylpentane-1-ol, 2-aminohexane-1-ol, 3-aminoheptane-4-ol, 1-aminooctane-2-ol, 5-aminooctane-4-ol, 1-aminopropane-2,3-diol, 2-aminopropane-1,3-diol, tris(oxymethyl)aminomethane, 1,2-diaminopropane-3-ol, 1,3-diaminopropane-2-ol, 2-(2-aminoethoxy)ethanol (DGA), hydroxyethylmorpholine, 1-(2-hydroxyethyl)piperdine, N-(2-hydroxyethyl)-2-pyrrolidone, or a mixture thereof.

Embodiment 11: The composition of embodiments 1-10, wherein the quaternary ammonium hydroxide is tetramethylammonium hydroxide (TMAH), tetraethylammonium hydroxide (TEAH), trimethylethylammonium hydroxide (TMEAH), benzyltrimethylammonium hydroxide (BTMAH), dimethyldipropylammonium hydroxide (DMDPAH), tetrapropylammonium hydroxide (TPAH), tetrabutylammonium hydroxide (TBAH), or a mixture thereof.

Embodiment 12: The composition of embodiments 1-4 and 6-11, wherein the composition does not include a polar aprotic solvent.

Embodiment 13: The composition of embodiments 1-12, wherein the polar protic solvent is tetrahydrofurfuryl alcohol (THFA), the alkanolamine is monoethanolamine (MEA), and the quaternary ammonium hydroxide is dimethyldipropyl ammonium hydroxide (DMDPAH).

Embodiment 14: A method comprising providing a substrate having a substance disposed on at least a portion of one surface of the substrate; and contacting the substrate and the substance with a composition comprising a polar protic solvent; an amine or alkanolamine; and a quaternary ammonium hydroxide.

Embodiment 15: A composition comprising from about 1 wt. % to about 75 wt. %. of a polar protic solvent; from about 1 wt. % to about 75 wt. % of an amine or a first alkanolamine; and from about 0.5 wt. % to about 50 wt. % of a second alkanolamine different from the first alkanolamine.

Embodiment 16: The composition of embodiment 15, wherein the polar protic solvent is present in an amount from about 20 wt. % to about 60 wt. %.

Embodiment 17: The composition of embodiments 15-16, wherein the first alkanolamine is present in an amount from about 4 wt. % to about 60 wt. %.

Embodiment 18: The composition of embodiments 15-17, wherein the amine is present in an amount from about 4 wt. % to about 60 wt. %.

Embodiment 19: The composition of embodiments 15-18, wherein the first alkanolamine is present in an amount from about 7 wt. % to about 50 wt. %.

Embodiment 20: The composition of embodiments 15-19, wherein the second alkanolamine is present in an amount from about 0.5 wt. % to about 20 wt. %.

Embodiment 21: The composition of embodiments 15-20, wherein the polar protic solvent is furfuryl alcohol (FFA), tetrahydrofurfuryl alcohol (THFA), benzyl alcohol, cyclohexanol, (4-methylcyclohexyl)methanol, hydroxymethylcyclohexane, m-cresol, or a mixture thereof.

Embodiment 22: The composition of claim embodiments 15-21, wherein the polar protic solvent comprises a cyclic molecule.

Embodiment 23: The composition of embodiments 15-22, wherein the first alkanolamine and second alkanolamine are each independently aminoethylethanolamine (AEEA), dimethylaminoethanol (DMAE), monoethanolamine (MEA), N-methylethanolamine, N-ethylethanolamine, N-propylethanolamine, N-butylethanolamine, diethanolamine, triethanolamine, N-methyldiethanolamine, N-ethyldiethanolamine, monoisopropanolamine (MIPA), diisopropanolamine, triisopropanolamine, N-methylisopropanolamine, N-ethylisopropanolamine, N-propylisopropanolamine, 2-aminopropane-1-ol, N-methyl-2-aminopropane-1-ol, N-ethyl-2-aminopropane-1-ol, 1-aminopropane-3-ol, N-methyl-1-aminopropane-3-ol, N-ethyl-1-aminopropane-3-ol, 1-aminobutane-2-ol, N-methyl-1-aminobutane-2-ol, N-ethyl-1-aminobutane-2-ol, 2-aminobutane-1-ol, N-methyl-2-aminobutane-1-ol, N-ethyl-2-aminobutane-1-ol, 3-aminobutane-1-ol, N-methyl-3-aminobutane-1-ol, N-ethyl-3-aminobutane-1-ol, 1-aminobutane-4-ol, N-methyl-1-aminobutane-4-ol, N-ethyl-1-aminobutane-4-ol, 1-amino-2-methylpropane-2-ol, 2-amino-2-methylpropane-1-ol, 1-aminopentane-4-ol, 2-amino-4-methylpentane-1-ol, 2-aminohexane-1-ol, 3-aminoheptane-4-ol, 1-aminooctane-2-ol, 5-aminooctane-4-ol, 1-aminopropane-2,3-diol, 2-aminopropane-1,3-diol, tris(oxymethyl)aminomethane, 1,2-diaminopropane-3-ol, 1,3-diaminopropane-2-ol, 2-(2-aminoethoxy)ethanol, (DGA), hydroxyethylmorpholine, 1-(2-hydroxyethyl)piperdine, N-(2-hydroxyethyl)-2-pyrrolidone, or a mixture thereof.

Embodiment 24: The composition of embodiments 15-23, further comprising from about 0.5 wt. % to about 25 wt. % of a third alkanolamine different from the first alkanolamine and different from the second alkanolamine.

Embodiment 25: The composition of embodiments 15-24, wherein the composition does not include a polar aprotic solvent.

Embodiment 26: The composition of embodiments 15-25, wherein the polar protic solvent is tetrahydrofurfuryl alcohol (THFA), the first alkanolamine is monoethanolamine (MEA), and the second alkanolamine is dimethylaminoethanol (DMAE) or monoisopropanolamine (MIPA).

Embodiment 27: The composition of embodiments 15-26, wherein the second alkanolamine is dimethylaminoethanol (DMAE) and further comprising a third alkanolamine that is monoisopropanolamine (MIPA).

Embodiment 28: A method comprising providing a substrate having a substance disposed on at least a portion of one surface of the substrate; and contacting the substrate and the substance with a composition comprising a polar protic solvent; an amine or a first alkanolamine; and a second alkanolamine different from the first alkanolamine.

Embodiment 29: A composition comprising tetrahydrofurfuryl alcohol (THFA), furfuryl alcohol (FFA), or benzylalcohol (BA); monoethanolamine (MEA); and a quaternary ammonium hydroxide or an alkanolamine other than MEA, wherein the composition does not include a polar aprotic solvent.

1. A composition comprising:
from about 1 wt. % to about 90 wt. %. of a polar protic solvent;
from about 1 wt. % to about 75 wt. % of an amine or alkanolamine; and
from about 0.5 wt. % to about 10 wt. % of quaternary ammonium hydroxide.

2. The composition of claim 1, wherein the polar protic solvent is present from about 25 wt. % to about 75 wt. %.

3. The composition of claim 1, further comprising an polar aprotic solvent in an amount no greater than about 20 wt. %.

4. The composition of claim 3, wherein the polar aprotic solvent is present in an amount no greater than about 10 wt. %.

5. The composition of claim 4, wherein the polar aprotic solvent is present in an amount no greater than about 2 wt. %.

6. The composition of claim 1, wherein the amine or alkanolamine is present in an amount from about 20 wt. % to about 50 wt. %.

7. The composition of claim 1, wherein the polar protic solvent is furfuryl alcohol (FFA), tetrahydrofurfuryl alcohol (THFA), benzyl alcohol, cyclohexanol, (4-methylcyclohexyl)methanol, hydroxymethylcyclohexane, m-cresol, or a mixture thereof.

8. The composition of claim 1, wherein the polar protic solvent comprises a cyclic molecule.

9. The composition of claim 1, wherein the amine is diethylenetriamine (DETA), triethylenetetramine (TETA), tetraethylenepentamine, dimethylbenzylamine, malonamide, tetrahydrofurfurylamine, furfuyl amine, or a mixture thereof.

10. The composition of claim 1, wherein the alkanolamine is aminoethylethanolamine (AEEA), dimethylaminoethanol (DMAE), monoethanolamine (MEA), N-methylethanolamine, N-ethylethanolamine, N-propylethanolamine, N-butylethanolamine, diethanolamine, triethanolamine, N-methyldiethanolamine, N-ethyldiethanolamine, monoisopropanolamine (MIPA), diisopropanolamine, triisopropanolamine, N-methylisopropanolamine, N-ethylisopropanolamine, N-propylisopropanolamine, 2-aminopropane-1-ol, N-methyl-2-aminopropane-1-ol, N-ethyl-2-aminopropane-1-ol, 1-aminopropane-3-ol, N-methyl-1-aminopropane-3-ol, N-ethyl-1-aminopropane-3-ol, 1-aminobutane-2-ol, N-methyl-1-aminobutane-2-ol, N-ethyl-1-aminobutane-2-ol, 2-aminobutane-1-ol, N-methyl-2-aminobutane-1-ol, N-ethyl-2-aminobutane-1-ol, 3-aminobutane-1-ol, N-methyl-3-aminobutane-1-ol, N-ethyl-3-aminobutane-1-ol, 1-aminobutane-4-ol, N-methyl-1-aminobutane-4-ol, N-ethyl-1-aminobutane-4-ol, 1-amino-2-methylpropane-2-ol, 2-amino-2-methylpropane-1-ol, 1-aminopentane-4-ol, 2-amino-4-methylpentane-1-ol, 2-aminohexane-1-ol, 3-aminoheptane-4-ol, 1-aminooctane-2-ol, 5-aminooctane-4-ol, 1-aminopropane-2,3-diol, 2-aminopropane-1,3-diol, tris(oxymethyl)aminomethane, 1,2-diaminopropane-3-ol, 1,3-diaminopropane-2-ol, 2-(2-aminoethoxy)ethanol (DGA), hydroxyethylmorpholine, 1-(2-hydroxyethyl)piperdine, N-(2-hydroxyethyl)-2-pyrrolidone, or a mixture thereof.

11. The composition of claim 1, wherein the quaternary ammonium hydroxide is tetramethylammonium hydroxide (TMAH), tetraethylammonium hydroxide (TEAH), trimethylethylammonium hydroxide (TMEAH), benzyltrimethylammonium hydroxide (BTMAH), dimethyldipropylammonium hydroxide (DMDPAH), tetrapropylammonium hydroxide (TPAH), tetrabutylammonium hydroxide (TBAH), or a mixture thereof.

12. The composition of claim 1, wherein the composition does not include a polar aprotic solvent.

13. The composition of claim 1, wherein the polar protic solvent is tetrahydrofurfuryl alcohol (THFA), the alkanolamine is monoethanolamine (MEA), and the quaternary ammonium hydroxide is dimethyldipropyl ammonium hydroxide (DMDPAH).

14. A method comprising:
providing a substrate having a substance disposed on at least a portion of one surface of the substrate; and
contacting the substrate and the substance with a composition comprising:
a polar protic solvent;
an amine or alkanolamine; and
a quaternary ammonium hydroxide.

15. A composition comprising:
from about 1 wt. % to about 75 wt. %. of a polar protic solvent;
from about 1 wt. % to about 75 wt. % of an amine or a first alkanolamine; and
from about 0.5 wt. % to about 50 wt. % of a second alkanolamine different from the first alkanolamine.

16. The composition of claim 15, wherein the polar protic solvent is present in an amount from about 20 wt. % to about 60 wt. %.

17. The composition of claim 15, wherein the first alkanolamine or amine is present in an amount from about 4 wt. % to about 60 wt. %.

18. The composition of claim 15, wherein the amine is present in an amount from about 4 wt. % to about 60 wt. %.

19. The composition of claim 15, wherein the first alkanolamine is present in an amount from about 7 wt. % to about 50 wt. %.

20. The composition of claim 15, wherein the second alkanolamine is present in an amount from about 0.5 wt. % to about 20 wt. %.

21. The composition of claim 15, wherein the polar protic solvent is furfuryl alcohol (FFA), tetrahydrofurfuryl alcohol (THFA), benzyl alcohol, cyclohexanol, (4-methylcyclohexyl)methanol, hydroxymethylcyclohexane, m-cresol, or a mixture thereof.

22. The composition of claim 15, wherein the polar protic solvent comprises a cyclic molecule.

23. The composition of claim 15, wherein the first alkanolamine and second alkanolamine are each independently aminoethylethanolamine (AEEA), dimethylaminoethanol (DMAE), monoethanolamine (MEA), N-methylethanolamine, N-ethylethanolamine, N-propylethanolamine, N-butylethanolamine, diethanolamine, triethanolamine, N-methyldiethanolamine, N-ethyldiethanolamine, monoisopropanolamine (MIPA), diisopropanolamine, triisopropanolamine, N-methylisopropanolamine, N-ethylisopropanolamine, N-propylisopropanolamine, 2-aminopropane-1-ol, N-methyl-2-aminopropane-1-ol, N-ethyl-2-aminopropane-1-ol, 1-aminopropane-3-ol, N-methyl-1-aminopropane-3-ol, N-ethyl-1-aminopropane-3-ol, 1-aminobutane-2-ol, N-methyl-1-aminobutane-2-ol, N-ethyl-1-aminobutane-2-ol, 2-aminobutane-1-ol, N-methyl-2-aminobutane-1-ol, N-ethyl-2-aminobutane-1-ol, 3-aminobutane-1-ol, N-methyl-3-aminobutane-1-ol, N-ethyl-3-aminobutane-1-ol, 1-aminobutane-4-ol, N-methyl-1-aminobutane-4-ol, N-ethyl-1-aminobutane-4-ol, 1-amino-2-methyl propane-2-ol, 2-amino-2-methylpropane-1-ol, 1-aminopentane-4-ol, 2-amino-4-methylpentane-1-ol, 2-aminohexane-1-ol, 3-aminoheptane-4-ol, 1-aminooctane-2-ol, 5-aminooctane-4-ol, 1-aminopropane-2,3-diol, 2-aminopropane-1,3-diol, tris(oxymethyl)aminomethane, 1,2-diaminopropane-3-ol, 1,3-diaminopropane-2-ol, 2-(2-aminoethoxy)ethanol, (DGA), hydroxyethylmorpholine, 1-(2-hydroxyethyl)piperdine, N-(2-hydroxyethyl)-2-pyrrolidone, or a mixture thereof.

24. The composition of claim 15, further comprising from about 0.5 wt. % to about 25 wt. % of a third alkanolamine different from the first alkanolamine and different from the second alkanolamine.

25. The composition of claim 15, wherein the composition does not include a polar aprotic solvent.

26. The composition of claim 15, wherein the polar protic solvent is tetrahydrofurfuryl alcohol (THFA), the first alkanolamine is monoethanolamine (MEA), and the second alkanolamine is dimethylaminoethanol (DMAE) or monoisopropanolamine (MIPA).

27. The composition of claim 25, wherein the second alkanolamine is dimethylaminoethanol (DMAE) and further comprising a third alkanolamine that is monoisopropanolamine (MIPA).

28. A method comprising:
providing a substrate having a substance disposed on at least a portion of one surface of the substrate; and
contacting the substrate and the substance with a composition comprising:
a polar protic solvent;
an amine or a first alkanolamine; and
a second alkanolamine different from the first alkanolamine.

29. A composition comprising:
tetrahydrofurfuryl alcohol (THFA), furfuryl alcohol (FFA), or benzylalcohol (BA);
monoethanolamine (MEA); and
a quaternary ammonium hydroxide or an alkanolamine other than MEA, wherein the composition does not include a polar aprotic solvent.

30. The composition of claim 1, wherein the polar protic solvent comprises furfuryl alcohol (FFA), tetrahydrofurfuryl alcohol (THFA), benzyl alcohol, cyclohexanol, (4-methylcyclohexyl)methanol, hydroxymethylcyclohexane, m-cresol, or a mixture thereof; and
wherein the composition comprises an amine comprising diethylenetriamine (DETA), triethylenetetramine (TETA), tetraethylenepentamine, benzyl amine, dimethylbenzylamine, malonamide, tetrahydrofurfurylamine, furfuyl amine, or a mixture thereof; and
wherein the quaternary ammonium hydroxide comprises tetramethylammonium hydroxide (TMAH), tetraethylammonium hydroxide (TEAH), trimethylethylammonium hydroxide (TMEAH), benzyltrimethylammonium hydroxide (BTMAH), dimethyldipropylammonium hydroxide (DMDPAH), tetrapropylammonium hydroxide (TPAH), tetrabutylammonium hydroxide (TBAH), or a mixture thereof.

31. The composition of claim 30, wherein the polar protic solvent comprises furfuryl alcohol (FFA), tetrahydrofurfuryl alcohol (THFA), benzyl alcohol, or a mixture thereof; and
wherein the composition comprises an amine comprising benzyl amine, dimethylbenzylamine, tetrahydrofurfurylamine, furfuyl amine, or a mixture thereof; and
wherein the quaternary ammonium hydroxide comprises tetramethylammonium hydroxide (TMAH), tetraethylammonium hydroxide (TEAH)—dimethyldipropylammonium hydroxide (DMDPAH), or a mixture thereof.

32. The composition of claim 1, comprising:
benzyl alcohol in an amount of from 1 wt. % to 90 wt. %;
benzyl amine in an amount of from 1 wt. % to 75 wt. %; and
tetramethyl ammonium hydroxide or tetraethyl ammonium hydroxide in an amount of from 0.5 wt. % to 10 wt.

33. The composition of claim 32, comprising:
benzyl alcohol in an amount of greater than 70 wt. %;
benzyl amine in an amount of no greater than 50 wt. %; and
tetramethyl ammonium hydroxide or tetraethyl ammonium hydroxide in an amount of not greater than 6 wt. %.

34. The composition of claim 33, further comprising not more than 1 wt. % of a polar aprotic solvent.
